(19) United States
(12) Patent Application Publication
(10) Pub. No.: US 2020/0357877 A1
(43) Pub. Date: Nov. 12, 2020

(54) DISPLAY DEVICE

(71) Applicant: SAMSUNG DISPLAY CO., LTD., Yongin-si (KR)

(72) Inventors: Chaehan Hyun, Yongin-si (KR); Jongwon Park, Yongin-si (KR)

(21) Appl. No.: 16/802,913

(22) Filed: Feb. 27, 2020

(30) Foreign Application Priority Data
May 9, 2019 (KR) 10-2019-0054520

(51) Int. Cl. H01L 27/32; H01L 51/52

(52) U.S. Cl. CPC H01L 27/3276; H01L 51/5206; H01L 27/124; H01L 27/3216; H01L 27/3218; H01L 27/3246

(57) ABSTRACT

A display device includes a plurality of node electrodes, a conductive layer above the plurality of node electrodes and including first extensions extending in a first direction and second extensions extending in a second direction intersecting the first direction, a plurality of pixel electrodes above the conductive layer, and an insulating layer covering an edge of each of the plurality of pixel electrodes, where a plurality of openings respectively corresponding to a portion of each of the plurality of pixel electrodes is defined in the insulating layer, a center of each of the plurality of openings overlaps one of intersections between the first and second extensions and the conductive layer overlaps the plurality of node electrodes.

This application claims priority to Korean Patent Application No. 10-2019-0054520, filed on May 9, 2019, and all the benefits accruing therefrom under 35 U.S.C. § 119, the content of which in its entirety is herein incorporated by reference.

### BACKGROUND

### 1. Field

Exemplary embodiments relate to a display device.

### 2. Description of the Related Art

As a display field for visually expressing various electrical signal information has been rapidly developed, various display devices having excellent characteristics such as thinness, light weight, and low power consumption have been introduced.

### SUMMARY

In a case of a display device of high resolution, a display element, a plurality of transistors and capacitors for driving the display element, and conductive lines for transmitting signals to the display element are overlapped with each other, and various issues may arise accordingly.

Exemplary embodiments include an organic light-emitting display device capable of minimizing an asymmetric color shift phenomenon and ensuring excellent visibility while minimizing a characteristic difference between pixels.

An exemplary embodiment of a display device includes a plurality of node electrodes, a conductive layer above the plurality of node electrodes and including first extensions extending in a first direction and second extensions extending in a second direction intersecting the first direction, a plurality of pixel electrodes above the conductive layer, and an insulating layer covering an edge of each of the plurality of pixel electrodes, where a plurality of openings respectively corresponding to a portion of each of the plurality of pixel electrodes is defined in the insulating layer, a center of each of the plurality of openings overlaps one of intersections of the first and second extensions and the conductive layer overlaps the plurality of node electrodes.

In an exemplary embodiment, the first extensions may include first sub conductive lines and second sub conductive lines alternately arranged with the first sub-conductive lines, and the second extensions may include third sub conductive lines and fourth sub conductive lines alternately arranged with the third sub conductive lines.

In an exemplary embodiment, the third sub conductive lines may overlap the plurality of node electrodes.

In an exemplary embodiment, a width of the third sub conductive lines may be greater than a width of the fourth sub conductive lines.

In an exemplary embodiment, the plurality of pixel electrodes may include a first pixel electrode of a first pixel emitting a first color, a second pixel electrode of a second pixel emitting a second color, and a third pixel electrode of a third pixel emitting a third color, where the first pixel electrode and the third pixel electrode are alternately arranged in the first direction and the second direction, and the second pixel electrode may be repeatedly arranged in the first direction and the second direction and separated in a diagonal direction away from the first pixel electrode and the third pixel electrode.

In an exemplary embodiment, the first pixel electrode and the third pixel electrode may respectively overlap node electrodes at opposite sides of intersections between the first sub conductive lines and the third sub conductive lines.

In an exemplary embodiment, the plurality of openings of the insulating layer may include a first opening corresponding to a portion of the first pixel electrode, a second opening corresponding to a portion of the second pixel electrode, and a third opening corresponding to a portion of the third pixel electrode.

In an exemplary embodiment, each of a center of the first opening and a center of the third opening may overlap one of first intersections between the first sub conductive lines and the third sub conductive lines, and a center of the second opening may overlap one of second intersections between the second sub conductive lines and the fourth sub conductive lines.

In an exemplary embodiment, the display device may further include a plurality of conductive lines extending in the first direction in a same layer as the plurality of node electrodes, and electrically connected to the conductive layer.

In an exemplary embodiment, the plurality of node electrodes may be between the plurality of conductive lines in the second direction.

In an exemplary embodiment, the plurality of conductive lines may transmit a power supply voltage to pixels.

An exemplary embodiment of a display device includes a plurality of node electrodes, a conductive layer above the plurality of node electrodes and including first extensions extending in a first direction and second extensions extending in a second direction intersecting the first direction, a plurality of pixel electrodes above the conductive layer, and an insulating layer covering an edge of each of the plurality of pixel electrodes, where a plurality of openings respectively corresponding to a portion of each of the plurality of pixel electrodes is defined in the insulating layer, a center of each of first openings of the plurality of openings overlaps one of intersections of the first and second extensions, a center of each of second openings of the plurality of openings does not overlap the intersections, and the conductive layer overlaps the plurality of node electrodes.

In an exemplary embodiment, the second extensions may overlap the plurality of node electrodes.

In an exemplary embodiment, the first extensions may include first sub conductive lines and second sub conductive lines alternately arranged with the first sub conductive lines.

In an exemplary embodiment, the plurality of pixel electrodes may include a first pixel electrode of a first pixel emitting a first color, a second pixel electrode of a second pixel emitting a second color, and a third pixel electrode of a third pixel emitting a third color, where the first pixel electrode and the third pixel electrode are alternately arranged in the first direction and the second direction, and the second pixel electrode may be repeatedly arranged in the first direction and the second direction and separated in a diagonal direction away from the first pixel electrode and the third pixel electrode.

In an exemplary embodiment, the first pixel electrode and the third pixel electrode may respectively overlap node electrodes at opposite sides of intersections between the first sub conductive lines and the second extensions.

In an exemplary embodiment, the first openings may include an opening corresponding to a portion of the first pixel electrode and an opening corresponding to a portion of the third pixel electrode.

In an exemplary embodiment, the second openings may include an opening corresponding to a portion of the second pixel electrode.

In an exemplary embodiment, a center of each of the first openings may overlap one of intersections between the first sub conductive lines and the second extensions.

In an exemplary embodiment, the display device may further include a plurality of conductive lines extending in the first direction in a same layer as the plurality of node electrodes, and electrically connected to the conductive layer.

In an exemplary embodiment, the plurality of node electrodes may be between the plurality of conductive lines in the second direction.

### BRIEF DESCRIPTION OF THE DRAWINGS

These and/or other exemplary embodiments will become apparent and more readily appreciated from the following description of the exemplary embodiments, taken in conjunction with the accompanying drawings in which:

FIG. 1 is a plan view of an exemplary embodiment of a display device.

FIGS. 2A and 2C are equivalent circuit diagrams of an exemplary embodiment of a pixel PX of a display device, and FIGS. 2B and 2D illustrate another exemplary embodiment of portions of the pixels PX of FIGS. 2A and 2C, respectively.

FIG. 3 is a plan view of an exemplary embodiment of a light-emitting region of a plurality of pixels of an organic light-emitting display device.

FIG. 4 is a plan view showing an exemplary embodiment of a relationship between a light-emitting region of a pixel and a conductive layer, and

FIG. 5 is an enlarged view of portion A in FIG. 4.

FIG. 6 is a plan view showing another exemplary embodiment of a relationship between a light-emitting region of a pixel and a conductive layer.

FIG. 7 is an enlarged view of portion A′ of FIG. 6,

FIG. 8 is a cross-sectional view taken along line I-I′ of FIG. 7, and

FIG. 9 is a cross-sectional view taken along lines II-II′ and III-III′ of FIG. 7.

FIG. 10 is a plan view showing another exemplary embodiment of a relationship between a light-emitting region of a pixel and a conductive layer.

FIG. 11 is a plan view of an exemplary embodiment of positions of elements constituting a pixel.

FIGS. 12 to 17 are plan views of the elements of FIG. 11.

### DETAILED DESCRIPTION

Reference will now be made in detail to embodiments, examples of which are illustrated in the accompanying drawings, where like reference numerals refer to like elements throughout. In this regard, the exemplary embodiments may have different forms and should not be construed as being limited to the descriptions set forth herein. Accordingly, the exemplary embodiments are merely described below, by referring to the drawing figures, to explain exemplary embodiments of the description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the invention will be described in detail with reference to the accompanying drawings. The same reference numerals are used to denote the same elements, and repeated descriptions thereof will be omitted.

It will be understood that although the terms “first”, “second”, etc. may be used herein to describe various components, these components should not be limited by these terms.

An expression used in the singular encompasses the expression of the plural, unless it has a clearly different meaning in the context.

It will be further understood that the terms “comprises” and/or “comprising” used herein specify the presence of stated features or components, but do not preclude the presence or addition of one or more other features or components.

It will be understood that when a layer, region, or component is referred to as being “disposed on” another layer, region, or component, it may be directly or indirectly disposed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

When an exemplary embodiment may be implemented differently, a specific process order may be performed differently from the described order. In an exemplary embodiment, two consecutively described processes may be performed substantially at the same time or performed in an order opposite to the described order, for example.

It will be understood that when a layer, region, or component is connected to another portion, the layer, region, or component may be directly connected to the portion or an intervening layer, region, or component may exist. In an exemplary embodiment, when a layer, region, or component is electrically connected to another portion, the layer, region, or component may be directly electrically connected to the portion or may be indirectly connected to the portion through another layer, region, or component, for example.

In the following embodiments, the term “extension of a conductive line in a first direction or a second direction” means not only linear extension but also zigzag or curved extension in the first direction or the second direction.

In the following embodiments, the term “in a plan view” means that an object is viewed from above, and the term “in a cross-sectional view” means that a vertical section of an object is viewed from the side. In the following embodiments, “overlap” includes overlap “planar” overlap and “cross-sectional” overlap.

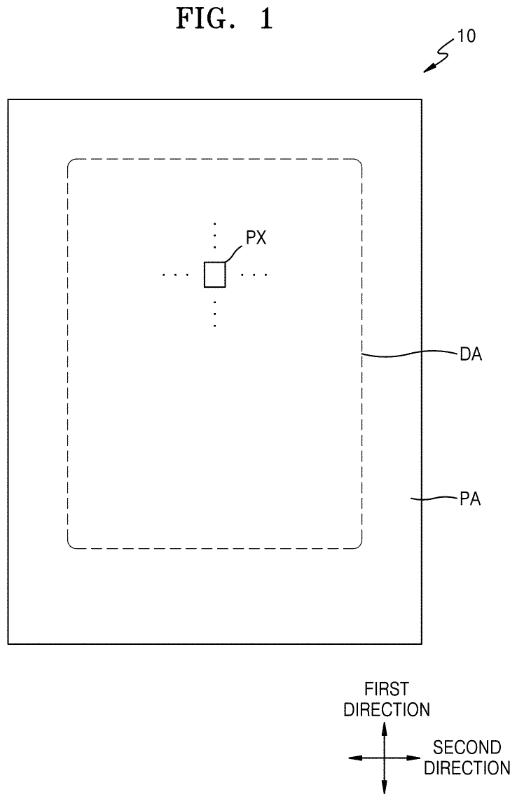

FIG. 1 is a plan view of an exemplary embodiment of a display device 10.

Referring to FIG. 1, the display device 10 in an exemplary embodiment includes a display area DA in which an image is implemented and a peripheral area PA that is a non-display area around the display area DA.

A plurality of pixels PX and conductive lines capable of applying electrical signals to the plurality of pixels PX may be disposed in the display area DA. The pixels PX may be arranged in a predetermined pattern in a first direction and a second direction intersecting the first direction.

Each of the plurality of pixels PX may include a display element and a pixel circuit for driving the display element. In an exemplary embodiment, the display element may be an organic light-emitting device, and the pixel circuit may include a plurality of transistors, a capacitor, and the like, for example.

The peripheral area PA is an area that does not provide an image and may include a scan driver and a data driver that provide electrical signals to be applied to the pixels PX of the display area DA, and power lines that provide power such as a driving voltage and a common voltage. In addition, the peripheral area PA may have a terminal portion to which a printed circuit board (“PCB”) or the like may be connected.

Although not shown, the display device 10 may be bent including a bending area in a portion of the peripheral area PA.

The display device 10 may be a display device such as an organic light-emitting display, an inorganic light emitting (“EL”), or a quantum dot light-emitting display. Hereinafter, an organic light-emitting display will be described as an example. In an exemplary embodiment, the display device 10 may be implemented by various kinds of electronic devices such as a mobile phone, a laptop computer, and a smart watch.

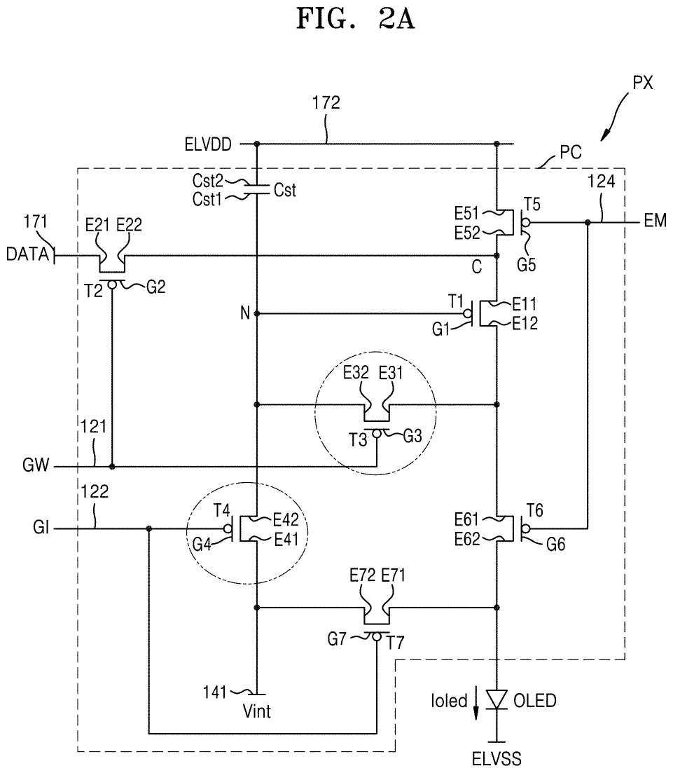

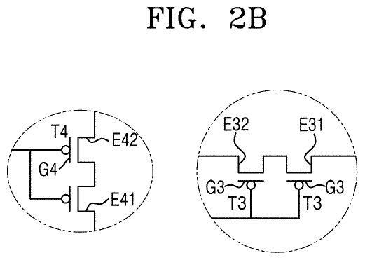

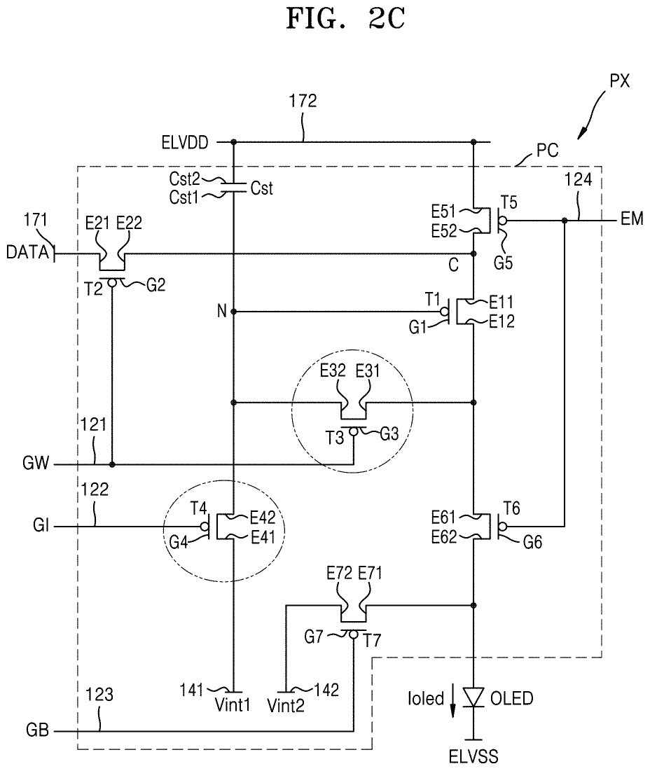

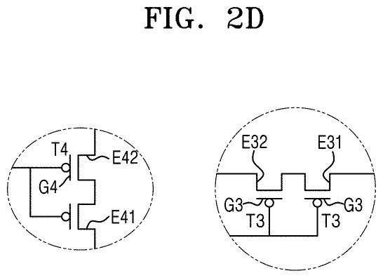

FIGS. 2A and 2C are equivalent circuit diagrams of an exemplary embodiment of one pixel PX that may be included in the display device 10. FIGS. 2B and 2D illustrate another exemplary embodiment of portions of the pixels PX of FIGS. 2A and 2C, respectively.

Referring to FIG. 2A, the pixel PX includes a display element and a pixel circuit PC that receives signals from a plurality of conductive lines and drives the display element. Hereinafter, the pixel PX including an organic light-emitting device OLED as the display element will be described as an example.

FIG. 2A shows that signal lines 121, 122, 124, and 171, an initialization voltage line 141, and a power supply voltage line 172 are provided for each pixel PX. However, the invention is not limited thereto. In another exemplary embodiment, at least one of the signal lines 121, 122, 124, and 171, the initialization voltage line 141 and/or the power supply voltage line 172 may be shared by neighboring pixels.

The signal lines include the first scan line 121 for transmitting a first scan signal GW, the second scan line 122 for transmitting a second scan signal GI, the emission control line 124 for transmitting an emission control signal EM, and the data line 171 which intersects the first scan line 121 and transmits a data signal DATA. The initialization voltage line 141 may transmit an initialization voltage Vint for initializing a first transistor T1 and the power supply voltage line 172 may transmit a first power supply voltage ELVDD to the first transistor T1.

The pixel circuit PC of the pixel PX may include a plurality of transistors T1 to T7 and a capacitor Cst. First electrodes E11 to E71 and second electrodes E12 to E72 of FIGS. 2A and 2C may be a source electrode (source region) or a drain electrode (drain region) depending on the type of transistor (p-type or n-type) and/or an operating condition.

The first transistor T1 includes a gate electrode G1, the first electrode E11 connected to the power supply voltage line 172 via the fifth transistor T5, and the second electrode E12 electrically connected to a pixel electrode of the organic light-emitting device OLED via the sixth transistor T6. The gate electrode G1 of the first transistor T1 is connected to a first electrode Cst1 of the capacitor Cst, the second electrode E32 of the third transistor T3, and the second electrode E42 of the fourth transistor T4 via a node N. The first transistor T1 serves as a driving transistor and receives the data signal DATA according to a switching operation of the second transistor T2 to supply a current to the organic light-emitting device OLED.

The second transistor T2 includes a gate electrode G2 connected to the first scan line 121, the first electrode E21 connected to the data line 171, and the second electrode E22 connected to the first electrode E11 of the first transistor T1. The second transistor T2 is turned on in response to the first scan signal GW received through the first scan line 121 and performs a switching operation to transmit the data signal DATA transmitted to the data line 171 to the first electrode Ell of the first transistor T1.

The third transistor T3 includes a gate electrode G3 connected to the first scan line 121, the first electrode E31 connected to the second electrode E12 of the first transistor T1, and the second electrode E32 connected to the first electrode Cst1 of the capacitor Cst, the second electrode E42 of the fourth transistor T4 and the gate electrode G1 of the first transistor T1. The first electrode E31 is connected to the pixel electrode of the organic light-emitting device OLED via the sixth transistor T6. The third transistor T3 is turned on in response to the first scan signal GW received through the first scan line 121 to diode-connect the first transistor T1.

The fourth transistor T4 includes a gate electrode G4 connected to the second scan line 122, the first electrode E41 connected to the first initialization voltage line 141, and the second electrode E42 connected to the first electrode Cst1 of the capacitor Cst, the second electrode E32 of the third transistor T3 and the gate electrode G1 of the first transistor T1. The fourth transistor T4 is turned on in response to the second scan signal GI received through the second scan line 122 to transmit the initialization voltage Vint to the gate electrode G1 of the first transistor T1, thereby initializing a gate voltage of the first transistor T1.

The fifth transistor T5 includes a gate electrode G5 connected to the emission control line 124, the first electrode E51 connected to the power supply voltage line 172, and the second electrode E52 connected to the first electrode E11 of the first transistor T1 and the second electrode E22 of the second transistor T2.

The sixth transistor T6 includes a gate electrode G6 connected to the emission control line 124, the first electrode E61 connected to the second electrode E12 of the first transistor T1 and the first electrode E31 of the third transistor T3, and a second electrode E62 connected to the pixel electrode of the organic light-emitting device OLED.

The fifth transistor T5 and the sixth transistor T6 are simultaneously turned on in response to the emission control signal EM received through the emission control line 124 so that a current flows to the organic light-emitting device OLED.

The seventh transistor T7 includes a gate electrode G7 connected to the second scan line 122, the first electrode E71 connected to the second electrode E62 of the sixth transistor T6 and the pixel electrode of the organic light-emitting device OLED, and the second electrode E72 to the first initialization voltage line 141. The seventh transistor T7 is turned on in response to the second scan signal GI received through the second scan line 122 to transmit the initialization voltage Vint to the pixel electrode of the organic light-emitting device OLED, thereby initializing the pixel electrode. In another exemplary embodiment, the seventh transistor T7 may be omitted.

The capacitor Cst may include the first electrode Cst1 connected to the gate electrode G1 of the first transistor T1 and a second electrode Cst2 connected to the power supply voltage line 172. The first electrode Cst1 of the capacitor Cst is also connected to the second electrode E32 of the third transistor T3 and the second electrode E42 of the fourth transistor T4.

The organic light-emitting device OLED may include a pixel electrode, an opposite electrode, and a light emitting layer between the pixel electrode and the opposite electrode. The opposite electrode may receive a second power supply voltage ELVSS. The organic light-emitting device OLED receives a driving current I_{oled} from the first transistor T1 and emits light to display an image.

In FIG. 2A, each of the third transistor T3 and the fourth transistor T4 has one gate electrode. In another exemplary embodiment, referring to FIG. 2B, the third transistor T3 may include a dual gate electrode, and two transistors may be connected in series. Likewise, the fourth transistor T4 may include a dual gate electrode, and two transistors may be connected in series.

Although the fourth transistor T4 and the seventh transistor T7 are connected to the second scan line 122 in FIG. 2A, the invention is not limited thereto. In another exemplary embodiment, the fourth transistor T4 may be connected to the second scan line 122 and the seventh transistor T7 may be connected to a separate conductive line to be driven according to a signal transmitted to the conductive line.

As shown in FIG. 2C, the signal line may further include a third scan line 123 for transmitting a third scan signal GB. The initialization voltage line may include the first initialization voltage line 141 for transmitting a first initialization voltage Vint1 and a second initialization voltage line 142 for transmitting a second initialization voltage Vint2.

The fourth transistor T4 includes a gate electrode G4 connected to the second scan line 122, the first electrode E41 connected to the first initialization voltage line 141, and the second electrode E42 connected to the first electrode Cst1 of the capacitor Cst, the second electrode E32 of the third transistor T3 and the gate electrode G1 of the first transistor T1. The fourth transistor T4 is turned on in response to the second scan signal GI received through the second scan line 122 to transmit the first initialization voltage Vint1 to the gate electrode G1 of the first transistor T1, thereby initializing the gate electrode G1 of the first transistor T1.

The seventh transistor T7 includes a gate electrode G7 connected to the third scan line 123, the first electrode E71 connected to the second electrode E62 of the sixth transistor T6 and the pixel electrode of the organic light-emitting device OLED, and the second electrode E72 connected to the second initialization voltage line 142. The seventh transistor T7 is turned on in response to the third scan signal GB received through the third scan line 123 to initialize the pixel electrode of the organic light-emitting device OLED. In an exemplary embodiment, the third scan line 123 may be the second scan line 122 of the next row and the third scan signal GB may be the second scan signal GI of the next row. In another exemplary embodiment, the seventh transistor T7 may be omitted.

In FIG. 2C, each of the third transistor T3 and the fourth transistor T4 has one gate electrode. In another exemplary embodiment, referring to FIG. 2D, the third transistor T3 may include a dual gate electrode, and two transistors may be connected in series. Likewise, the fourth transistor T4 may include a dual gate electrode, and two transistors may be connected in series.

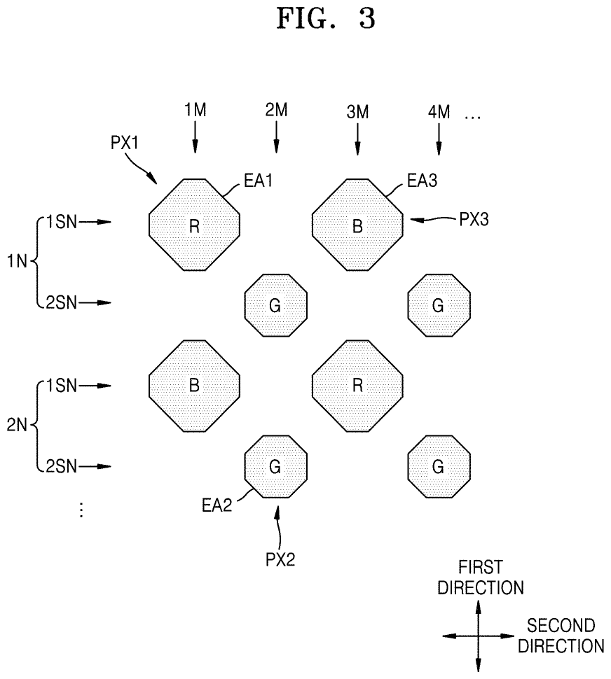

FIG. 3 is a plan view of an exemplary embodiment of a light-emitting region of a plurality of pixels of an organic light-emitting display device.

The plurality of pixels arranged in the display area DA may include a first pixel PX1, a second pixel PX2, and a third pixel PX3. The first pixel PX1, the second pixel PX2, and the third pixel PX3 may be repeatedly arranged in a first direction and a second direction according to a predetermined pattern. Each of the first pixel PX1, the second pixel PX2, and the third pixel PX3 may include a pixel circuit (refer to PC in FIGS. 2A and 2C) and the organic light-emitting device OLED electrically connected to the pixel circuit. The organic light-emitting device OLED of each pixel may be on an upper layer of the pixel circuit. The organic light-emitting device OLED may be directly on top of the pixel circuit so as to overlap the pixel circuit, or may be offset from the pixel circuit so as to partially overlap a pixel circuit of another pixel which is disposed in an adjacent row or column.

FIG. 3 shows a light-emitting region of each of the first pixel PX1, the second pixel PX2, and the third pixel PX3. The light-emitting region is a region in which a light emitting layer of the organic light-emitting device OLED is disposed. The light-emitting region may be defined by an opening of a pixel defining layer. This will be described later below.

The first pixel PX1 may include a first light-emitting region EA1, the second pixel PX2 may include a second light-emitting region EA2, the third pixel PX3 may include a third light-emitting region EA3.

In an odd column, the first light-emitting region EA1 of the first pixel PX1 and the third light-emitting region EA3 of the third pixel PX3 may be alternately arranged in a first direction. In an even column, the second light-emitting region EA2 of the second pixel PX2 may be repeatedly arranged in the first direction. In an exemplary embodiment, in a first column 1M, the first light-emitting region EA1 of the first pixel PX1 and the third light-emitting region EA3 of the third pixel PX3 may be alternately arranged in the first direction, for example. The second light-emitting region EA2 of the second pixel PX2 may be repeatedly arranged in the first direction in a second column 2M adjacent to the first column 1M. In a third column 3M adjacent to the second column 2M, contrary to the first column 1M, the third light-emitting region EA3 of the third pixel PX3 and the first light-emitting region EA1 of the first pixel PX1 may be alternately arranged in the first direction.

The first light-emitting region EA1 of the first pixel PX1 and the third light-emitting region EA3 of the third pixel PX3 are arranged in the second direction in a first sub row 1SN of each of rows 1N, 2N, . . . , etc., and the second light-emitting region EA2 of the second pixel PX2 may be repeatedly arranged in the second direction in a second sub row 2SN. That is, in each of rows 1N, 2N, . . . , etc., the first light-emitting region EA1 of the first pixel PX1, the second light-emitting region EA2 of the second pixel PX2, the third light-emitting region EA3 of the third pixel PX3, and the second light-emitting region EA2 of the second pixel PX2 may be alternately arranged in a zigzag manner.

The first light-emitting region EA1 of the first pixel PX1, the second light-emitting region EA2 of the second pixel PX2, and the third light-emitting region EA3 of the third pixel PX3 have different areas. In an exemplary embodiment, the third light-emitting region EA3 of the third pixel PX3 may be greater than the first light-emitting region EA1 of the first pixel PX1. In addition, the third light-emitting region EA3 of the third pixel PX3 may be greater than the second light-emitting region EA2 of the second pixel PX2. The first light-emitting region EA1 of the first pixel PX1 may be greater than the second light-emitting region EA2 of the second pixel PX2. In another exemplary embodiment, the third light-emitting region EA3 of the third pixel PX3 may have the same area as the first light-emitting region EA1 of the first pixel PX1. However, the invention is not limited thereto. In an exemplary embodiment, the first light-emitting region EA1 of the first pixel PX1 may be greater than the second light-emitting region EA2 of the second pixel PX2 and the third light-emitting region EA3 of the third pixel PX3, and various exemplary embodiments are possible, for example.

In an exemplary embodiment, the first to third light-emitting regions EA1, EA2, and EA3 may have a polygonal shape such as a quadrangle, an octagon, etc., a circular shape, an elliptical shape, and the like, where the polygonal shape may include a shape in which a vertex is rounded.

In an exemplary embodiment, the first pixel PX1 may be a red pixel R that emits red light, the second pixel PX2 may be a green pixel G that emits green light, and the third pixel PX3 may be a blue pixel B that emits blue light. In another exemplary embodiment, the first pixel PX1 may be the red pixel R, the second pixel PX2 may be the blue pixel B, and the third pixel PX3 may be the green pixel G.

In an exemplary embodiment of the invention, a pixel arrangement may be an arrangement of light-emitting regions. The pixel arrangement of the present invention is not limited to thereto. In an exemplary embodiment, the invention may be applied to a pixel array having a stripe arrangement, a mosaic arrangement, and a delta arrangement, for example. Furthermore, the invention may also be applied to a pixel array structure further including a white pixel that emits white light.

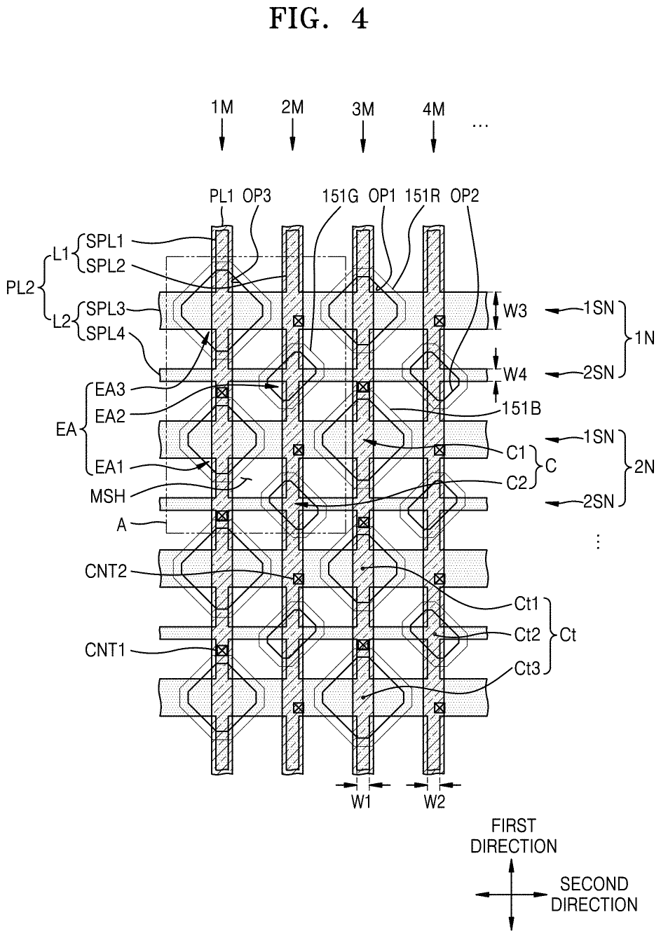

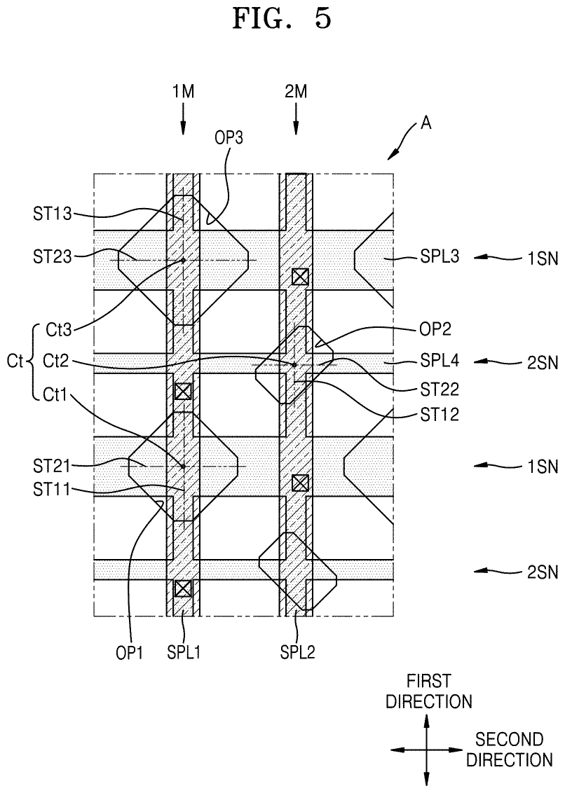

FIG. 4 is a plan view showing an exemplary embodiment of a relationship between a light-emitting region of a pixel and a conductive layer. FIG. 5 is an enlarged view of portion A in FIG. 4.

Referring to FIGS. 4 and 5, the display area DA may include a second conductive line PL2 connected to the plurality of pixels PX (refer to FIGS. 1 to 2A). The display area DA may further include first conductive lines PL1 electrically connected to the second conductive line PL2.

Each of the first conductive lines PL1 extends in the first direction and may be connected to a plurality of pixels arranged in the same column. In an exemplary embodiment, the first conductive line PL1 extending along the first column 1M may be connected to the first pixels PX1 (refer to FIG. 3) and the third pixels PX3 (refer to FIG. 3) which are alternately arranged, for example. The first conductive line PL1 extending along the second column 2M may be connected to the second pixels PX2 (refer to FIG. 3). The first conductive lines PL1 may be arranged overlapping a light-emitting region of the pixels in a plan view. The first conductive lines PL1 may be conductive lines to which a constant voltage is applied. In an exemplary embodiment, the first conductive lines PL1 may be the power supply voltage line 172 for transmitting the first power supply voltage ELVDD (refer to FIGS. 2A and 2C) to the plurality of pixels, for example. The first conductive lines PL1 may be apart at regular intervals in the second direction.

The second conductive line PL2 may be a conductive layer disposed on a different layer from the first conductive lines PL1. The second conductive line PL2 may be disposed on an upper layer of the first conductive lines PL1. The second conductive line PL2 may include a plurality of first extensions L1 and a plurality of second extensions L2. The plurality of first extensions L1 and the plurality of second extensions L2 may be unitary.

The plurality of first extensions L1 extends in the first direction and may be connected to a plurality of pixels arranged in the same column. The first extensions L1 may include a first sub conductive line SPL1 and a second sub conductive line SPL2 alternately arranged with the first sub conductive line SPL1. The first sub conductive line SPL1 extends along the odd columns 1M, 3M, . . . , etc., and may be connected to the first pixels PX1 and the third pixels PX3. The second sub conductive line SPL2 extends along even columns 2M, 4M, . . . , etc., and may be connected to the second pixels PX2. The first sub conductive line SPL1 may have a first width W1 and the second sub conductive line SPL2 may have a second width W2. The first width W1 and the second width W2 may be the same.

The second extensions L2 extend in the second direction and may be connected to a plurality of pixels arranged in the same row, respectively. Each of the second extensions L may include a third sub conductive line SPL3 and a fourth sub conductive line SPL4 alternately arranged with the third sub conductive line SPL3. The third sub conductive line SPL3 extends along the first sub row 1SN and may be connected to the first pixels PX1 and the third pixels PX3. The fourth sub conductive line SPL4 extends along the second sub row 2SN and may be connected to the second pixels PX2. The third sub conductive line SPL3 may have a third width W3 and the fourth sub conductive line SPL4 may have a fourth width W4. The third width W3 may be greater than the fourth width W4.

The second conductive line PL2 may have a mesh structure in which mesh-holes MSH are defined by intersecting the first extensions L1 and the second extensions L2. The first extensions L1 and second extensions L2 may intersect to form intersections C. The intersections C may include first intersections C1 and second intersections C2. The first intersections C1 may be provided by intersecting first sub conductive lines SPL1 and third sub conductive lines SPL3. The second intersections C2 may be provided by intersecting second sub conductive lines SPL2 and fourth sub conductive lines SPL4. In an exemplary embodiment, the first sub conductive lines SPL1 extending along the first column 1M may intersect with the third sub conductive lines SPL3 extending along the second direction to form the first intersections C1, for example. In addition, the second sub conductive lines SPL2 extending along the second column 2M may intersect with the fourth sub conductive lines SPL4 extending along the second direction to form the second intersections C2.

The second conductive lines PL2 may be in contact with the first conductive lines PL1 by a plurality of first contact holes CNT1 and the second contact holes CNT2. In an exemplary embodiment, the first sub conductive lines SPL1 may be in contact with the first conductive lines PL1 by the first contact holes CNT1 and the second sub conductive lines SPL2 may be in contact with the first conductive lines PL1 by the second contact holes CNT2, for example. As the second conductive lines PL2 contact the first conductive lines PL1, the second conductive line PL2 may provide the same voltage as the first conductive line PL1. In an exemplary embodiment, the first conductive line PL1 and the second conductive line PL2 may be conductive lines for transmitting the first power supply voltage ELVDD, for example. As the second conductive line PL2 is provided in the mesh structure, the first power supply voltage ELVDD may be uniformly provided throughout the display area DA (refer to FIG. 1).

The first contact holes CNT1 and the second contact holes CNT2 are arranged to overlap the first conductive line PL1 and may be arranged in the first direction along the first conductive line PL1. The first contact holes CNT1 and the second contact holes CNT2 may be arranged so as not to overlap a light-emitting region of pixels arranged in the first direction. In an exemplary embodiment, the first contact holes CNT1 arranged along the first column 1M may be arranged around the first light-emitting region EA1 of the first pixel PX1 and the third light-emitting region EA3 of the third pixel PX3, for example. The second contact holes CNT2 arranged along the second column 2M may be arranged around the second light-emitting region EA2 of the second pixel PX2. In an exemplary embodiment, the first contact holes CNT1 may be arranged at or around an intersection where the first sub conductive lines SPL1 and the fourth sub conductive lines SPL4 intersect. The second contact holes CNT2 may be arranged at or around an intersection where the second sub conductive lines SPL2 and the third sub conductive lines SPL3 intersect.

The arrangement of the second conductive line PL2, the first contact holes CNT1, and the second contact holes CNT2 according to the illustrated exemplary embodiment may be introduced to minimize an asymmetrical color shift according to a side viewing angle. That is, symmetry of a light-emitting region EA of a plurality of pixels is increased by designing intersection portion C of the first extensions L1 and the second extensions L2 to overlap each other in the light-emitting region EA. Furthermore, an influence of the first contact holes CNT1 and the second contact holes CNT2 on the pixels may be minimized by designing that the light-emitting region EA, the first contact holes CNT1, and the second contact holes CNT2 are not overlapped with each other.

First to third pixel electrodes 151R, 151G, and 151B of the first to third pixels PX1, PX2, and PX3 may be arranged on the second conductive line PL2. The first pixel electrode 151R of the first pixel PX1 and the third pixel electrode 151B of the third pixel PX3 may be alternately arranged in the first direction and the second direction, respectively. The first pixel electrode 151R of the first pixel PX1 and the third pixel electrode 151B of the third pixel PX3 may be alternately arranged in the first direction in odd columns and may be alternately arranged in the second direction in the first sub row 1SN of each of the rows 1N, 2N, . . . , etc. The second pixel electrode 151G of the second pixel PX2 may be diagonally spaced from the first pixel electrode 151R and the third pixel electrode 151B and may be repeatedly arranged in the first direction and the second direction. The second pixel electrode 151G of the second pixel PX2 may be repeatedly arranged in an even column in the first direction, and may be repeatedly arranged in the second direction in the second sub row 2SN in each of the rows 1N, 2N, . . . , etc.

Each of the first to third light-emitting regions EA1, EA2, and EA3 of the first to third pixels PX1, PX2, and PX3 may be a region corresponding to a portion of each of the first to third pixel electrodes 151R, 151G, and 151B. The first to third light-emitting regions EA1, EA2, and EA3 may be defined by first to third openings OP1, OP2, and OP3 provided in a pixel defining layer.

The first opening OP1 and the third opening OP3 may be vertically and horizontally symmetrical with respect to the first intersection C1 of the second conductive line PL2. The second opening OP2 may be vertically and horizontally symmetrical with reference to a second intersection C2 of the second conductive line PL2.

An imaginary straight line passing through each of centers Ct1, Ct2, and Ct3 of the first to third openings OP1, OP2, and OP3 may bisect a planar area of each of the first to third openings OP1, OP2, and OP3. That is, an imaginary straight line passing through each of the centers Ct1, Ct2, and Ct3 of the first to third light-emitting regions EA1, EA2, and EA3 may bisect a planar area of each of the first to third light-emitting regions EA1, EA2, and EA3. In an exemplary embodiment, a first straight line ST11 passing through the center Ct1 of the first light-emitting region EA1 of the first pixel PX1 in the first direction or a second straight line ST21 in the second direction may bisect a planar area of the first light-emitting region EA1 of the first pixel PX1, for example. Therefore, planar right and left areas of the first light-emitting region EA1 of the first pixel PX1 bisected by the first straight line ST11 may be the same. Also, planar up and down areas of the first light-emitting region EA1 of the first pixel PX1 bisected by the second straight line ST21 may be the same. As another example, a first straight line ST12 passing through the center Ct2 of the second light-emitting region EA2 of the second pixel PX2 in the first direction or a second straight line ST22 in the second direction may bisect a planar area of the second light-emitting region EA2 of the second pixel PX2. Therefore, planar right and left areas of the second light-emitting region EA2 of the second pixel PX2 bisected by the first straight line ST12 may be the same. Also, planar up and down areas of the second light-emitting region EA2 of the second pixel PX2 bisected by the second straight line ST22 may be the same. As another example, a first straight line ST13 passing through the center Ct3 of the third light-emitting region EA3 of the third pixel PX3 in the first direction or a second straight line ST23 in the second direction may bisect a planar area of the third light-emitting region EA3 of the third pixel PX3. Therefore, planar right and left areas of the third light-emitting region EA3 of the third pixel PX3 bisected by the first straight line ST13 may be the same. Also, planar up and down areas of the third light-emitting region EA3 of the third pixel PX3 bisected by the second straight line ST23 may be the same.

The first light-emitting region EA1 of the first pixel PX1 and/or the third light-emitting region EA3 of the third pixel PX3 may overlap any one of the first intersections C1, respectively. The second light-emitting region EA2 of the second pixel PX2 may overlap any one of the second intersections C2. That is, the light-emitting regions of the plurality of pixels may overlap one of the intersections, respectively.

A center Ct of the light-emitting region of each of the plurality of pixels may overlap any one of the intersections C of the second conductive line PL2. In an exemplary embodiment, the center Ct1 of the first light-emitting region EA1 of the first pixel PX1 and the center Ct3 of the third light-emitting region EA3 of the third pixel PX3 may overlap any one of the first intersections C1, respectively, for example. The center Ct2 of the second light-emitting region EA2 of the second pixel PX2 may overlap any one of the second intersections C2. The centers Ct of the light-emitting regions EA1, EA2, and EA3 of the plurality of pixels may overlap the first conductive lines PL1.

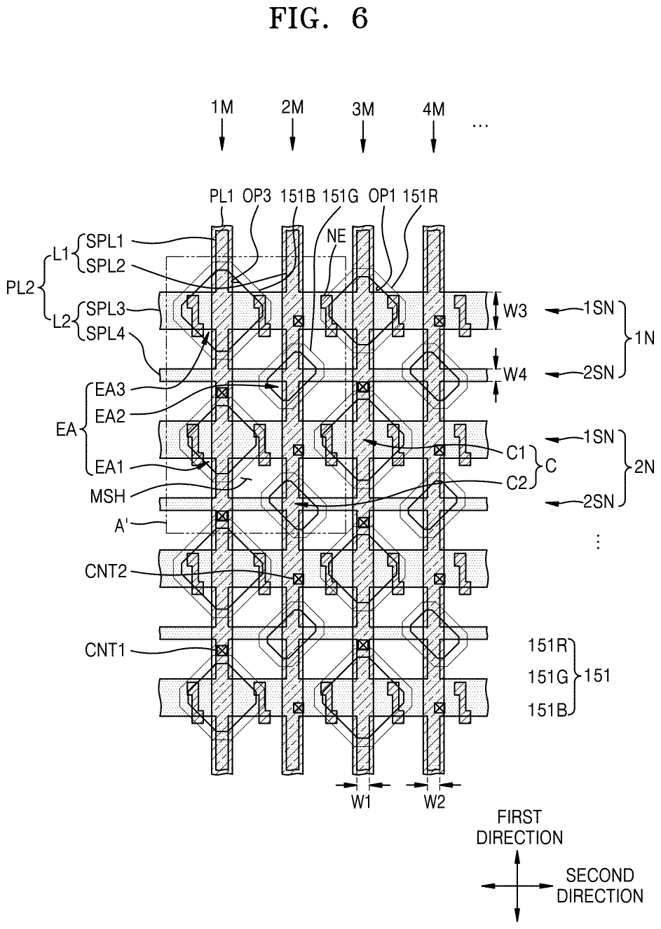

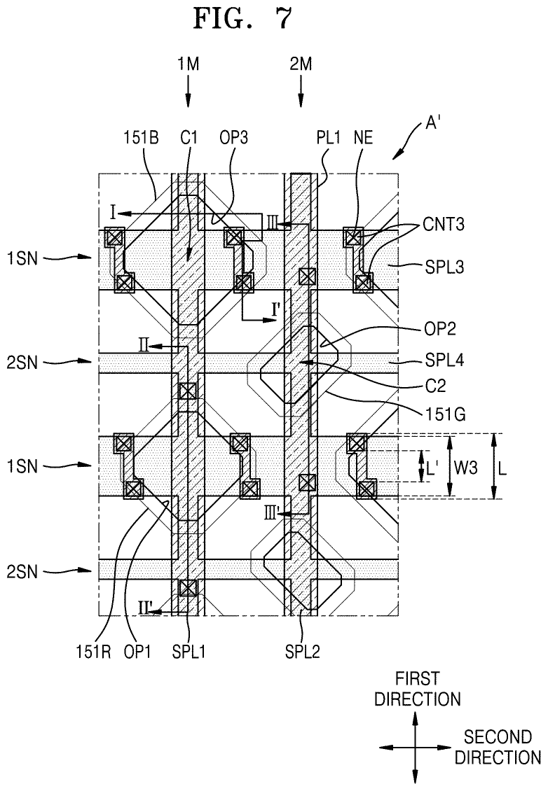

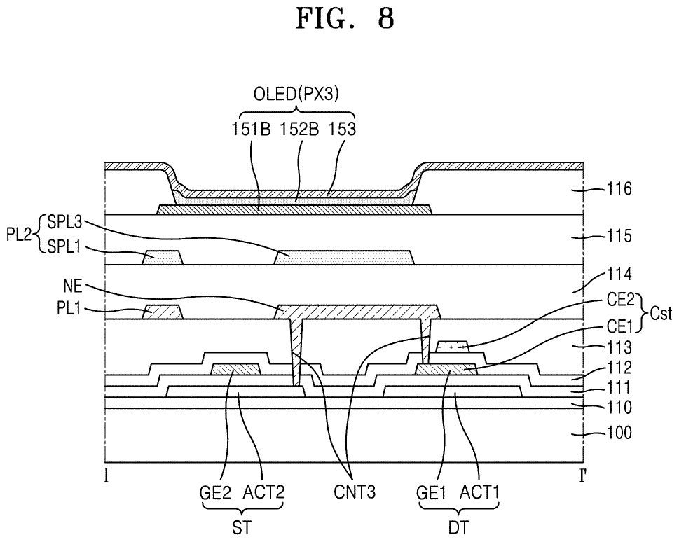

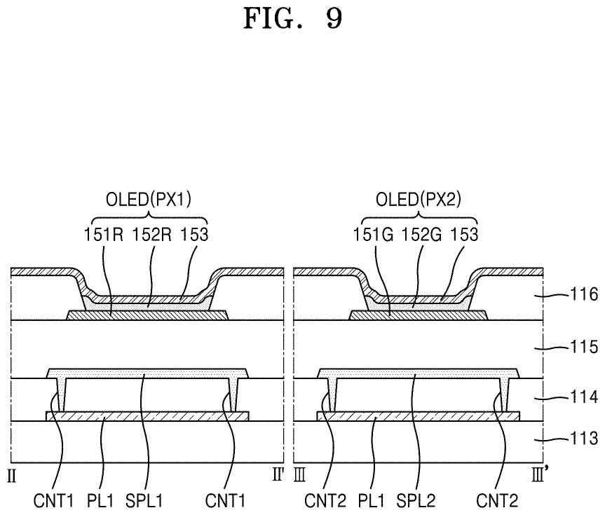

FIG. 6 is a plan view showing another exemplary embodiment of a relationship between a light-emitting region of a pixel and a conductive layer. FIG. 7 is an enlarged view of portion A′ in FIG. 6. FIG. 8 is a cross-sectional view taken along line I-I′ of FIG. 7, and FIG. 9 is a cross-sectional view taken along lines II-II′ and III-III′ of FIG. 7. In FIGS. 6 and 7, the same reference numerals in FIG. 4 denote the same elements, and a duplicate description will be omitted.

Referring to FIGS. 6 and 7, the display area DA may further include node electrodes NE spaced apart from the first conductive lines PL1 in the same layer as the first conductive lines PL1. A node electrode NE may be a bridge electrode for connecting transistors of the pixel circuit PC (refer to FIGS. 2A and 2C). The node electrode NE corresponds to the node N shown in FIGS. 2A and 2C, and may transmit a signal. In an exemplary embodiment, the node electrode NE may be a bridge electrode connecting the gate electrode G1 of the first transistor T1, the second electrode E32 of the third transistor T3, and the second electrode E42 of the fourth transistor T4, for example.

The node electrode NE may be arranged for each pixel along the first sub row 1SN. The node electrode NE may extend substantially in parallel with the first conductive line PL1 in the first direction, and may have a first length L. The node electrode NE may electrically connect at least two transistors through the third contact holes CNT3 at both ends.

The third sub conductive line SPL3 of the second conductive line PL2 may overlap the node electrode NE. The third sub conductive line SPL3 may have the third width W3 covering at least a second length L′ between the third contact holes CNT3 at both ends of the node electrode NE. That is, the third width W3 of the third sub conductive line SPL3 may be equal to or greater than the second length L′ of the node electrode NE. In FIG. 7, the third width W3 of the third sub conductive line SPL3 is substantially equal to the first length L of the node electrode NE. In another exemplary embodiment, the third width W3 of the third sub conductive line SPL3 covers an entirety of the first length L of the node electrode NE and may be equal to or greater than the first length L.

The first light-emitting region EA1 of the first pixel PX1 may correspond to a region where the first pixel electrode 151R is exposed by the first opening OP1 of a pixel defining layer. The second light-emitting region EA2 of the second pixel PX2 may correspond to a region where the second pixel electrode 151G is exposed by the second opening OP2 of the pixel defining layer. The third light-emitting region EA3 of the third pixel PX3 may correspond to a region where the third pixel electrode 151B is exposed by the third opening OP3 of the pixel defining layer.

The first pixel electrode 151R of the first pixel PX1 may overlap any one of the first intersections C1 of the second conductive line PL2. The second pixel electrode 151G of the second pixel PX2 may overlap any of the second intersections C2 of the second conductive line PL2. The third pixel electrode 151B of the third pixel PX3 may overlap any one of the first intersections C1 of the second conductive line PL2. That is, the pixel electrodes of the plurality of pixels may overlap any one of the intersections, respectively.

The center Ct of each of the plurality of openings of the pixel defining layer may be the center Ct of the light-emitting region of each of the plurality of pixels. The center Ct of the plurality of openings may overlap any one of the intersections C of the second conductive line PL2. Each of the center Ct1 of the first opening OP1 and the center Ct3 of the third opening OP3 may overlap any one of the first intersections C1. The center Ct2 of the second opening OP2 may overlap any of the second intersections C2. The center Ct of each of the plurality of openings may overlap the first conductive lines PL1.

The first pixel electrode 151R of the first pixel PX1 and the third pixel electrode 151B of the third pixel PX3 may at least partially overlap at least one node electrode NE. The first pixel electrode 151R of the first pixel PX1 and the third pixel electrode 151B of the third pixel PX3 may at least partially overlap each of the node electrodes NE arranged on the left and right sides of the first intersection C1. In an exemplary embodiment, the first pixel electrode 151R of the first pixel PX1 may partially overlap the node electrode NE of the first pixel PX1 on the right side of the first intersection C1 and the node electrode NE of the second pixel PX2 of a column adjacent to the left side of the first intersection C1, for example. The third pixel electrode 151B of the third pixel PX3 may partially overlap the node electrode NE of the third pixel PX3 on the right side of the first intersection C1 and the node electrode NE of the second pixel PX2 of the column adjacent to the left side of the first intersection C1. The third sub conductive line SPL3 may be disposed in a layer between the first pixel electrode 151R and the node electrode NE and between the third pixel electrode 151B and the node electrode NE.

As the node electrode NE of the second pixel PX2 partially overlaps the first pixel electrode 151R of the first pixel PX1 or the third pixel electrode 151B of the third pixel PX3 that are adjacent to the second pixel PX2, a cross talk may be generated between the node electrode NE of the second pixel PX2 and a pixel electrode of an adjacent pixel. In an exemplary embodiment, a cross talk phenomenon between the node electrode NE of the second pixel PX2 and the pixel electrode of the adjacent pixel which is shifted from the pixel circuit PC of the adjacent pixel, may be minimized by disposing the third sub conductive line SPL3 as a shielding member between the node electrode NE of the second pixel PX2 and the pixel electrode of the adjacent pixel.

A stacked structure of a display device and a positional relationship of the node electrode NE, the first conductive line PL1, and the second conductive line PL2 according to the illustrated exemplary embodiment will be described with reference to FIGS. 8 and 9.

A substrate 100 may include various materials such as a glass material, a metal material, a plastic material, or the like. In an exemplary embodiment, the substrate 100, which may be a flexible substrate, may include a polymer resin such as polyethersulphone (“PES”), polyacrylate, polyetherimide (“PEI”), polyethylene naphthalate (“PEN”), polyethylene terephthalate (“PET”), polyphenylene sulfide (“PPS”), polyarylate (“PAR”), polyimide (“PI”), polycarbonate (“PC”), or cellulose acetate propionate (“CAP”). The substrate 100 may have a multilayer structure including a layer including the above-described polymer resin and an inorganic layer (not shown).

The buffer layer 110 may include an inorganic material, such as an oxide or nitride, an organic material, or an organic-inorganic composite material, and may have a single layer structure or a multilayer structure including an inorganic material and/or an organic material. A barrier layer (not shown) may be further between the substrate 100 and the buffer layer 110 to block penetration of outside material. In another exemplary embodiment, the buffer layer 110 may be omitted.

A pixel circuit of each pixel and the organic light-emitting device OLED electrically connected to the pixel circuit may be arranged on the substrate 100. The pixel circuit may include a first thin-film transistor (“TFT”) DT, a second TFT ST, and the capacitor Cst. The first TFT DT may be a driving transistor and the second TFT ST may be a switching transistor.

The fact that the organic light-emitting device OLED is electrically connected to the pixel circuit may be that a pixel electrode 151 is electrically connected to the first TFT DT or the second TFT ST. The first TFT DT may be the first transistor T1 of FIGS. 2A and 2C and the second TFT ST may be one of the second to seventh transistors T2, T3, T4, T5, T6, and T7.

The first TFT DT may include a semiconductor layer ACT1 and a gate electrode GE1. The second TFT ST may include a semiconductor layer ACT2 and a gate electrode GE2. The semiconductor layers ACT1 and ACT2 may include amorphous silicon, polycrystalline silicon, or an organic semiconductor material. In another exemplary embodiment, the semiconductor layers ACT1 and ACT2 may include an oxide of at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn), for example. The semiconductor layers ACT1 and ACT2 may include a source region, a drain region, and a channel region between the source region and the drain region. In an exemplary embodiment, a source region and a drain region of the first TFT DT and the second TFT ST may be a source electrode and a drain electrode, respectively. In another exemplary embodiment, the first TFT DT and the second TFT ST may further include a source electrode and a drain electrode which respectively contact the source region and the drain region.

In an exemplary embodiment, the gate electrodes GE1 and GE2 may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may be a single layer or multiple layers, for example.

The first insulating layer 111 may be between the semiconductor layers ACT1 and ACT2 and the gate electrodes GE1 and GE2. The first insulating layer 111 may include inorganic insulating materials such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first insulating layer 111 may be a single layer or multiple layers including the above-described inorganic insulating materials.

A second insulating layer 112 may be above the gate electrodes GE1 and GE2 and cover the gate electrodes GE1 and GE2. In an exemplary embodiment, the second insulating layer 112 may include inorganic insulating materials such as SiO₂, SiNₓ, SiON, Al₂O₃, TiO₂, Ta₂O₅, HfO₂, or ZnO₂. The second insulating layer 112 may be a single layer or multiple layers including the above-described inorganic insulating materials.

The capacitor Cst includes a lower electrode CE1 and an upper electrode CE2 which overlap each other with the second insulating layer 112 therebetween. The capacitor Cst may overlap the first TFT DT. FIG. 8 shows that the gate electrode GE1 of the first TFT DT is the lower electrode CE1 of the capacitor Cst. In another exemplary embodiment, the capacitor Cst may not overlap the first TFT DT. In an exemplary embodiment, the upper electrode CE2 of the capacitor Cst may include Al, Pt, Pd, Ag, Mg, Au, Ni, Nd, Ir, Cr, Li, Ca, Mo, Ti, W and/or Cu, for example, and may be a single layer or multiple layers of the above-described material. The capacitor Cst may be covered with a third insulating layer 113.

In an exemplary embodiment, the third insulating layer 113 may include SiO₂, SiNₓ, SiON, Al₂O₃, TiO₂, Ta₂O₅, HfO₂, or ZnO₂, for example. The third insulating layer 113 may be a single layer or multiple layers including the above-described inorganic insulating materials.

The first conductive line PL1 and the node electrode NE may be on the third insulating layer 113. In an exemplary embodiment, the first conductive line PL1 may include a conductive material such as Mo, Al, Cu, and Ti and may be a single layer or multiple layers including the above-described material. In an exemplary embodiment, the first conductive line PL1 may have a multilayer structure of Ti/Al/Ti, for example. The node electrode NE may be disposed in the same layer as the first conductive line PL1 and may include the same material as that of the material of the first conductive line PL1. The node electrode NE may include a conductive material including Mo, Al, Cu, Ti, or the like, and may be a single layer or multiple layers including the above-described material. The first conductive line PL1 and the node electrode NE may be arranged for each pixel. FIG. 8 shows an example in which the node electrode NE connects the gate electrode GE1 of the first TFT DT and the semiconductor layer ACT2 of the second TFT ST.

Although not shown, the source electrode and the drain electrode may be further in the same layer as the first conductive line PL1, that is, on the third insulating layer 113. Further, a data line may be further in the same layer as the first conductive line PL1, that is, on the third insulating layer 113. The data line may extend in the first direction parallel to the first conductive line PL1. The data line may be disposed for each pixel.

A pixel circuit including the first and second TFTs DT and ST and the capacitor Cst may be covered with a fourth insulating layer 114 and a fifth insulating layer 115. The fourth insulating layer 114 may be on the third insulating layer 113 to cover the first conductive line PL1 and the node electrode NE. The second conductive line PL2 may be on the fourth insulating layer 114. The fourth insulating layer 114 may have a flat top surface so that the second conductive line PL2 thereon may be provided flat. The fifth insulating layer 115 may be on the fourth insulating layer 114 so as to cover the second conductive line PL2.

The fourth insulating layer 114 and the fifth insulating layer 115 may be an organic insulating layer as a planarization insulating layer. The fourth insulating layer 114 and the fifth insulating layer 115 may be a single layer or multiple layers constituting a film including an organic material or an inorganic material. In an exemplary embodiment, the fourth insulating layer 114 and the fifth insulating layer 115 may include a general purpose polymer such as benzocyclobutene (“BCB”), polyimide (“PI”), hexamethyldisiloxane (“HMDSO”), polymethylmethacrylate (“PMMA”), and polystyrene (“PS”), a polymer derivative including a phenolic group, an acrylic polymer, an imide polymer, an aryl ether polymer, an amide polymer, a fluorine-based polymer, a p-xylene-based polymer, a vinyl alcohol polymer, or a blend thereof. In another exemplary embodiment, the fourth insulating layer 114 and the fifth insulating layer 115 may include inorganic insulating materials such as SiO₂, SiNₓ, SiON, Al₂O₃, TiO₂, Ta₂O₅, HfO₂, or ZnO₂.

In an exemplary embodiment, the second conductive line PL2 may include Al, Pt, Pd, Ag, Mg, Au, Ni, Nd, Ir, Cr, Li, Ca, Mo, Ti, W and/or Cu, for example, and may be a single layer or multiple layers of the above-described material. The first sub conductive line SPL1 and the second sub conductive line SPL2 of the second conductive line PL2 may overlap the first conductive lines PL1.

The second conductive line PL2 may be in contact with the first conductive line PL1 through the first contact holes CNT1 and the second contact holes CNT2 passing through the fourth insulating layer 114. The first sub conductive line SPL1 of the second conductive line PL2 may be in contact with the first conductive line PL1 through the first contact holes CNT1 passing through the fourth insulating layer 114. The second sub conductive line SPL2 of the second conductive line PL2 may be in contact with the first conductive line PL1 through the second contact holes CNT2 passing through the fourth insulating layer 114.

The first contact holes CNT1 may be arranged along the first direction between the first pixel electrode 151R of the first pixel PX1 and the third pixel electrode 151B of the third pixel PX3. The second contact holes CNT2 may be arranged in along the first direction between second pixel electrodes 151G of the second pixel PX2. In each row, the first contact holes CNT1 and the second contact holes CNT2 may be alternately arranged in a zigzag manner in the second direction.

The organic light-emitting device OLED may be on the fifth insulating layer 115. The organic light-emitting device OLED may include a pixel electrode 151, intermediate layers 152R, 152G and 152B, and an opposite electrode 153.

The first to third pixel electrodes 151R, 151G, and 151B are on the fifth insulating layer 115. In an exemplary embodiment, the first to third pixel electrodes 151R, 151G, and 151B may include a conductive oxide such as indium tin oxide (“ITO”), indium zinc oxide (“IZO”), zinc oxide (“ZnO”), indium oxide (In₂O₃), indium gallium oxide (“IGO”), or aluminum zinc oxide (“AZO”). In another exemplary embodiment, the first to third pixel electrodes 151R, 151G, and 151B may include a reflective layer including Ag, Mg, Al, Pt, Pd, Au, Ni, Nd, Ir, Cr, or a combination thereof, for example. In another exemplary embodiment, the first to third pixel electrodes 151R, 151G, and 151B may further include a film including ITO, IZO, ZnO, or In2O3 above/below the reflective film. In some exemplary embodiments, the first to third pixel electrodes 151R, 151G, and 151B may be provided in a structure stacked with ITO/Ag/ITO, for example.

A sixth insulating layer 116 may be on the fifth insulating layer 115. The sixth insulating layer 116 may cover edges of the first to third pixel electrodes 151R, 151G, and 151B. The sixth insulating layer 116 may be a pixel defining layer that defines light-emitting regions of the first to third pixels by defining the first to third openings OP1, OP2, and OP3 corresponding to a portion of each of the first to third pixel electrodes 151R, 151G, and 151B. The sixth insulating layer 116 may prevent an arc from being generated at the edges of the first to third pixel electrodes 151R, 151G, and 151B by increasing distances between the edges of the first to third pixel electrodes 151R, 151G, and 151B and the opposite electrode 153. In an exemplary embodiment, the sixth insulating layer 116 may include organic insulating materials such as PI, polyamide, acrylic resin, BCB, HMDSO, and phenolic resin.

Each of the first to third pixel electrodes 151R, 151G, and 151B may at least partially overlap the first conductive line PL1 and the second conductive line PL2. The first pixel electrode 151R of the first pixel PX1 and the third pixel electrode 151B of the third pixel PX3 may at least partially overlap the node electrode NE. The third opening OP3 of the sixth insulating layer 116, which is a light-emitting region of the first pixel PX1, or the third opening OP3 of the sixth insulating layer 116, which is the light-emitting region of the third pixel PX3, may at least partially overlap at least one node electrode NE. The first opening OP1 or the third opening OP3 of the sixth insulating layer 116 may at least partially overlap two node electrodes NE. The second opening OP2 does not overlap the node electrode NE.

The second conductive line PL2 is disposed between the node electrode NE of the second pixel PX2 and the first pixel electrode 151R and between the node electrode NE of the second pixel PX2 and the third pixel electrode 151B. Therefore, influence on brightness of the second pixel PX2 may be minimized even when the node electrode NE of the second pixel PX2 overlaps a pixel electrode or a light-emitting region of an adjacent pixel.

Intermediate layers 152R, 152G, and 152B including a light emitting layer are on the first to third pixel electrodes 151R, 151G, and 151B exposed by the first to third openings OP1, OP2, and OP3 of the sixth insulating layer 116.

The intermediate layers 152R, 152G, and 152B include a light emitting layer. The light emitting layer may include a polymer or a low-molecular organic material that emits light of a predetermined color. In an exemplary embodiment, the intermediate layers 152R, 152G, and 152B may include a first functional layer under the light emitting layer and/or a second functional layer over the light emitting layer. The first functional layer and/or the second functional layer may include a unitary layer over the plurality of first to third pixel electrodes 151R, 151G, and 151B, and may include a patterned layer corresponding to each of the plurality of first to third pixel electrodes 151R, 151G, and 151B.

The first functional layer may be a single layer or multiple layers. In an exemplary embodiment, when the first functional layer includes a polymer material, for example, the first functional layer may be a hole transport layer (“HTL”) having a single-layer structure and may include poly-(3,4-ethylenedioxythiophene) (“PEDOT”) or polyaniline (“PANI”). When the first functional layer includes a low molecular material, the first functional layer may include a hole injection layer (“HIL”) and the HTL.

The second functional layer is optional. In an exemplary embodiment, when the first functional layer and the light emitting layer include a polymer material, for example, it is preferable to form the second functional layer in order to improve characteristics of an organic light-emitting device. The second functional layer may be a single layer or multiple layers. The second functional layer may include an electron transport layer (“ETL”) and/or an electron injection layer (“EIL”).

The opposite electrode 153 faces the first to third pixel electrodes 151R, 151G, and 151B with the intermediate layers 152R, 152G, and 152B therebetween. The opposite electrode 153 may include a conductive material having a low work function. In an exemplary embodiment, the opposite electrode 153 may include a (semi) transparent electrode including Ag, Mg, Al, Pt, Pd, Au, Ni, Nd, Ir, Cr, or an alloy thereof, for example. In an alternative exemplary embodiment, the opposite electrode 153 may further include a layer such as ITO, IZO, ZnO, or In₂O₃ on the (semi)transparent layer including the above-mentioned material.

The opposite electrode 153 may be unitary with a plurality of organic light-emitting devices OLED in the display area DA to face the plurality of first to third pixel electrodes 151R, 151G, and 151B.

Although not shown, a capping layer may be disposed on the opposite electrode 153 to improve light extraction efficiency while protecting the opposite electrode 153. The capping layer may include LiF. In an alternative exemplary embodiment, the capping layer may include inorganic insulating materials such as silicon nitride and/or organic insulating materials. In some exemplary embodiments, the capping layer may be omitted.

In addition, a sealing member may be further provided on the opposite electrode 153 to protect the plurality of organic light-emitting devices OLED from outside materials. The sealing member may be provided with a thin-film encapsulation layer including at least one inorganic encapsulation layer and at least one organic encapsulation layer. In an exemplary embodiment, the inorganic encapsulation layer may include one or more inorganic insulating materials such as aluminum oxide, titanium oxide, tantalum oxide, hafnium oxide, zinc oxide, silicon oxide, silicon nitride, and silicon oxynitride. The organic encapsulation layer may include a polymer-based material. Examples of the polymer-based material may include an acrylic resin, an epoxy resin, polyimide, and polyethylene. The thin-film encapsulation layer may have a structure in which a first inorganic encapsulation layer, an organic encapsulation layer, and a second inorganic encapsulation layer are stacked. In an alternative exemplary embodiment, as the sealing member, a sealing substrate which is bonded to the substrate 100 by sealant or frit may be used.

On the sealing member, components such as an input sensing member for sensing a touch input, an antireflection member including a polarizer and a retarder or a color filter and a black matrix, and a transparent window may be further arranged.

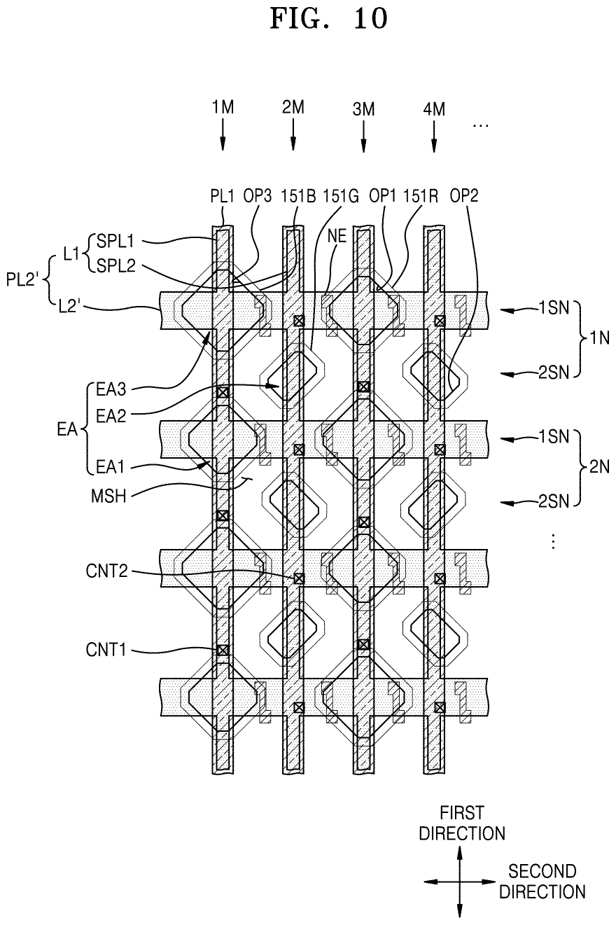

FIG. 10 is a plan view showing another exemplary embodiment of a relationship between a light-emitting region of a pixel and a conductive layer. In FIG. 10, the same reference numerals in FIGS. 4 and 6 denote the same elements, and a duplicate description will be omitted.

Referring to FIG. 10, a second conductive line PL2′ may include the first extensions L1 extending in the first direction and second extensions L2′ extending in the second direction. The first extensions L1 may include the first sub conductive line SPL1 and the second sub conductive line SPL2 alternately arranged with the first sub conductive line SPL1.

The second extensions L2′ extends along the first sub row 1SN and may be connected to the first pixels PX1 and the third pixels PX3. The first light-emitting region EA1 of the first pixel PX1 and the third light-emitting region of the third pixel PX3 may be disposed on intersections between the second extensions L2′ and the first sub conductive lines SPL1. Each of centers of the first opening OP1 and the third opening OP3 of the pixel defining layer may overlap one of the intersections between the second extensions L2′ and the first sub conductive lines SPL1. That is, the first opening OP1 and the third opening OP3 of the pixel defining layer may be disposed at the intersections between the second extensions L2′ and the first sub conductive lines SPL1. The second extensions L2′ do not pass through the second light-emitting region EA2 of the second pixel PX2, and therefore, unlike the exemplary embodiment shown in FIG. 6, the second intersections C2 where the second extensions L2′ and the second sub conductive lines SPL2 intersect may not be provided. Accordingly, the second conductive line PL2′ is provided in the first direction and the second direction below the first light-emitting region EA1 of the first pixel PX1 and the third light-emitting region EA3 of the third pixel PX3. However, the second conductive line PL2′ may be disposed only in the first direction below the second light-emitting region EA2 of the second pixel PX2.

The exemplary embodiment of FIG. 10 may reduce an overlapping area of the second conductive line PL2′ and other conductive lines of a lower layer, thereby reducing possibility of short circuit between the second conductive line PL2′ and a lower conductive line. In an exemplary embodiment, it is possible to reduce an overlapping area of the second conductive line PL2′ and a data line, thereby reducing possibility of short circuit between the second conductive line PL2′ and the data line and reducing a load on the data line, for example.

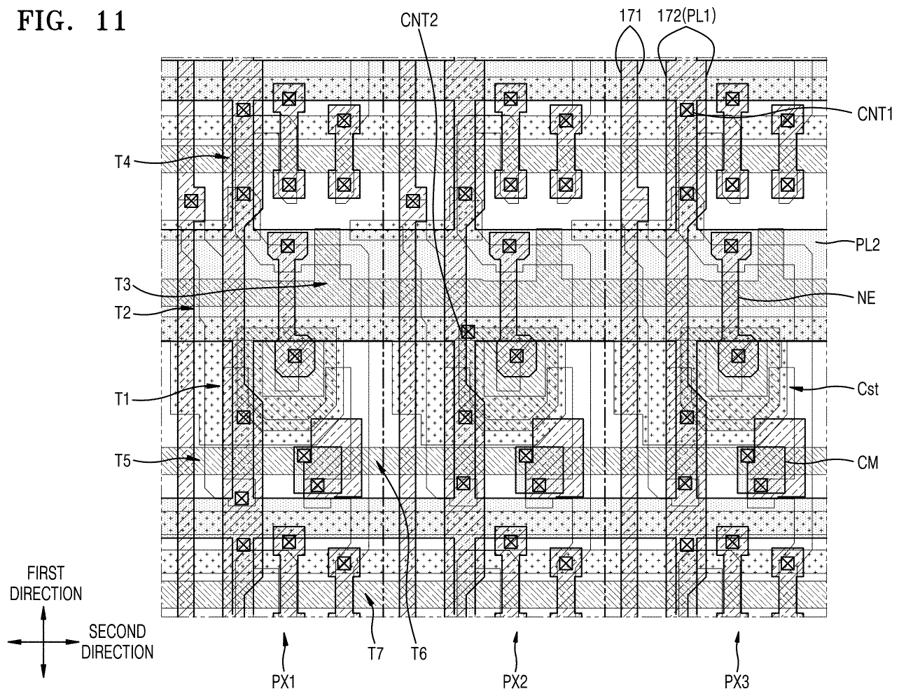

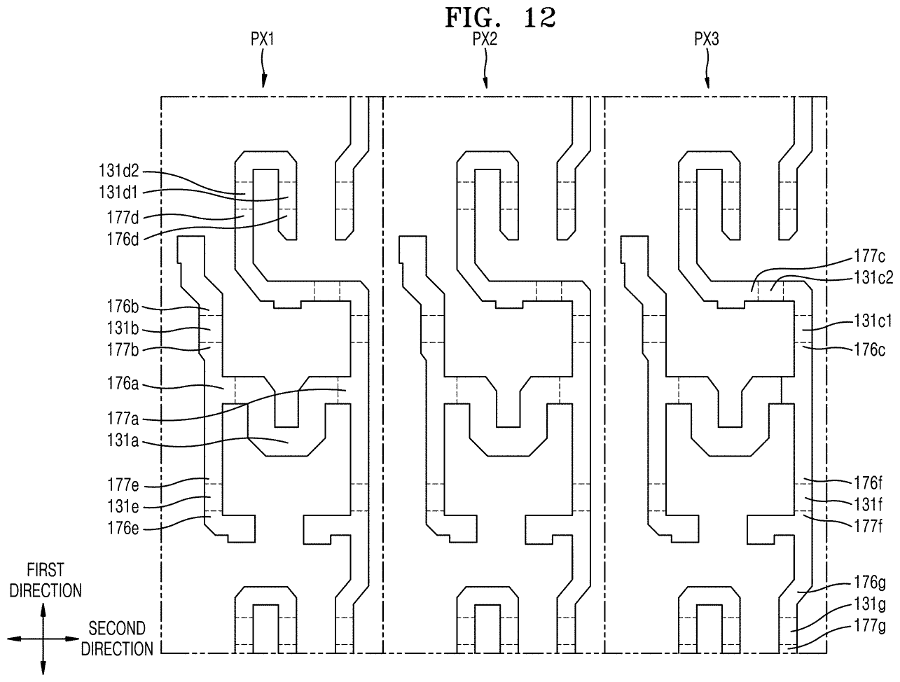

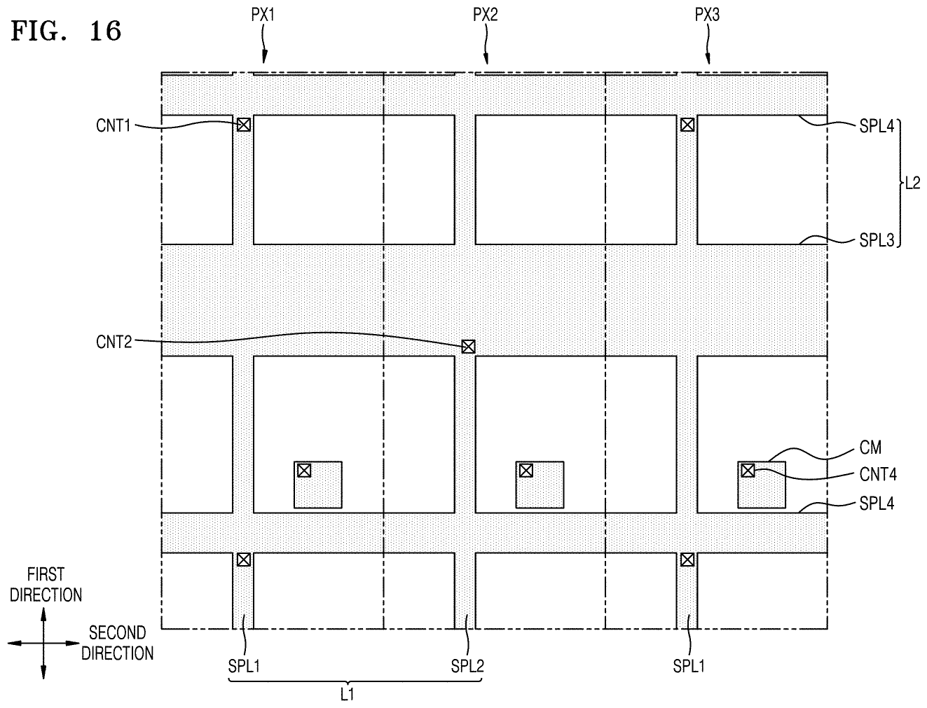

FIG. 11 is a plan view of an exemplary embodiment of positions of elements constituting a pixel. FIGS. 12 to 17 are plan views of the elements of FIG. 11.

FIG. 11 may correspond to a plan view of the pixel shown in FIG. 2C. In FIGS. 11 to 17, the detailed description of the same constitution as the layers described with reference to FIGS. 8 and 9 will not be given herein. The first to seventh transistors T1 to T7 shown in FIG. 2C may be implemented as TFTs.

A semiconductor layer may be on the buffer layer 110 of the substrate 100. The semiconductor layer may have a curved shape in various shapes, and the first to third pixels PX1, PX2, and PX3 may include semiconductor layers of the same shape. Hereinafter, when respective layers of the first to third pixels PX1, PX2, and PX3 have the same shape, they are not separately described.

As shown in FIG. 12, the semiconductor layer may include a channel region 131a of the first transistor T1, a channel region 131b of the second transistor T2, channel regions 131c1 and 131c2 of the third transistor T3, channel regions 131d1 and 131d2 of the fourth transistor T4, a channel region 131e of the fifth transistor T5, a channel region 131f of the sixth transistor T6, and a channel region 131g of the seventh transistor T7. That is, it is understood that each channel region of the first to seventh transistors T1 to T7 is a portion of the semiconductor layer. The channel region 131a of the first transistor T1 has a curve so that a driving range of a gate voltage applied to a gate electrode may be widened. In an exemplary embodiment, the shape of the channel region 131a of the first transistor T1 may be [symbol] , [symbol] , ‘S’, ‘M’, ‘W’, and the like, for example. The channel region 131g of the seventh transistor T7 may be a portion of the semiconductor layer extending in the next row.

Each of the semiconductor layers of the first to seventh transistors T1 to T7 may include a channel region and a source region and a drain region on both sides of the channel region. As shown in FIG. 12, the semiconductor layer may include a source region 176a and a drain region 177a of the first transistor T1, a source region 176b and a drain region 177b of the second transistor T2, a source region 176c and a drain region 177c of the third transistor T3, a source region 176d and a drain region 177d 9of the fourth transistor T4, a source region 176e and a drain region 177e of the fifth transistor T5, a source region 176f and a drain region 177f of the sixth transistor T6, and a source region 176g and a drain region 177g of the seventh transistor T7. The source region or the drain region may be a source electrode or a drain electrode of a transistor in some cases. That is, for example, a source electrode and a drain electrode of the first transistor T1 may respectively correspond to the source region 176a and the drain region 177a doped with impurities near the channel region 131a in the semiconductor layer shown in FIG. 12. The first insulating layer 111 may be on the semiconductor layer.

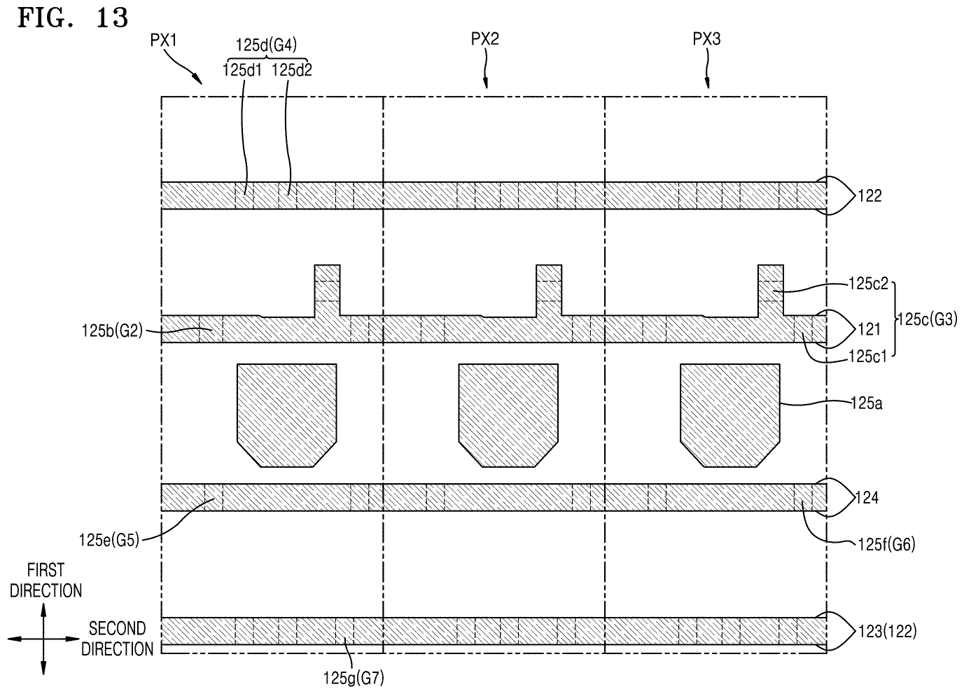

As shown in FIG. 13, a gate electrode 125a of the first transistor T1, a gate electrode 125b of the second transistor T2, gate electrodes 125c1 and 125c2 of the third transistor T3, gate electrodes 125d1 and 125d2 of the fourth transistor T4, a gate electrode 125e of the fifth transistor T5, a gate electrode 125f of the sixth transistor T6, and a gate electrode 125g of the transistor T7 may be above the first insulating layer 111. Furthermore, on a first insulating layer 111, the first scan line 121, the second scan line 122, the third scan line 123, and the emission control line 124 may extend in the second direction with the same material and in the same layer as those of gate electrodes of the first to seventh transistors T1 to T7. The third scan line 123 may be the second scan line 122 of the next row.

The gate electrode 125b of the second transistor T2 and the gate electrodes 125c1 and 125c2 of the third transistor T3 may be either portions of the first scan line 121 intersecting the semiconductor layer or portions protruding from the first scan line 121. The gate electrodes 125d1 and 125d2 of the fourth transistor T4 may be either portions of the second scan line 122 crossing the semiconductor layer or portions protruding from the second scan line 122. The gate electrode 125e of the fifth transistor T5 and the gate electrode 125f of the sixth transistor T6 may be either portions of the emission control line 124 intersecting the semiconductor layer or portions protruding from the emission control line 124. The gate electrode 125g of the seventh transistor T7 may be portions of the third scan line 123 intersecting the semiconductor layer in the next row or portions protruding from the third scan line 123. The gate electrode 125a of the first transistor T1 may be an island type. The gate electrode 125a of the first transistor T1 may be the lower electrode CE1 which is a first electrode of the capacitor Cst. The second insulating layer 112 may be above the gate electrodes of the first to seventh transistors T1 to T7.

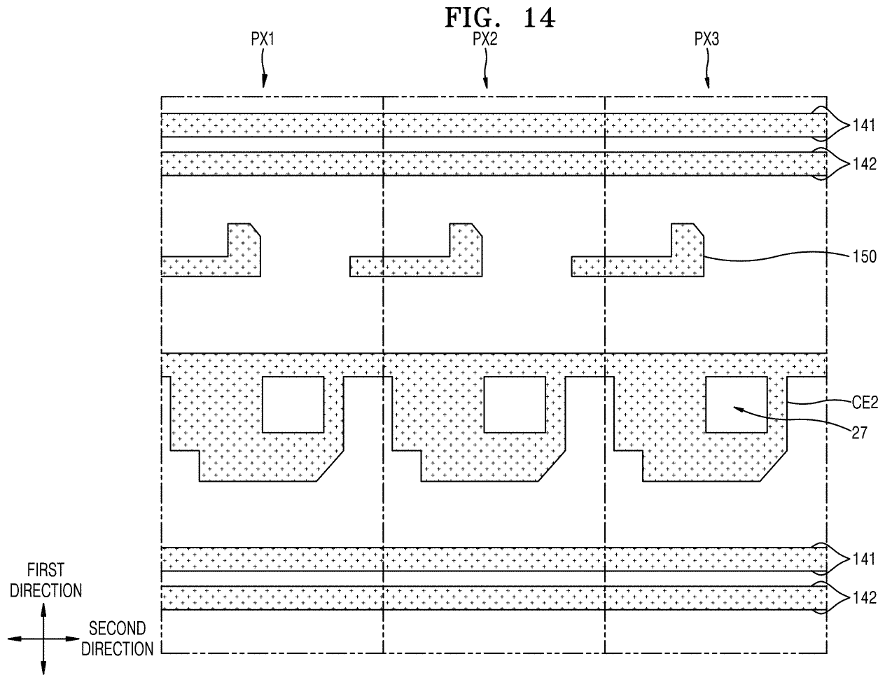

As shown in FIG. 14, the upper electrode CE2, which is a second electrode of the capacitor Cst, may be above the second insulating layer 112. An opening 27 may be defined in the upper electrode CE2 of the capacitor Cst. The node electrode NE may be electrically connected to the lower electrode CE1 of the capacitor Cst and the drain region 177c of the third transistor T3 through the opening 27. Upper electrodes CE2 of the capacitors Cst of the first to third pixels PX1, PX2 and PX3 may be connected to each other.

On a second insulating layer 112, the first initialization voltage line 141 and the second initialization voltage line 142 may be in the same layer as the upper electrode CE2 of the capacitor Cst. The first initialization voltage line 141 and the second initialization voltage line 142 may extend in the second direction and be spaced apart from each other in the first direction. A shielding member 150 may be further above the second insulating layer 112. The shielding member 150 may overlap a portion of the drain region 177c of the third transistor T3 and a portion of the drain region 177d of the fourth transistor T4.

The third insulating layer 113 may be above the upper electrode CE2 of the capacitor Cst.

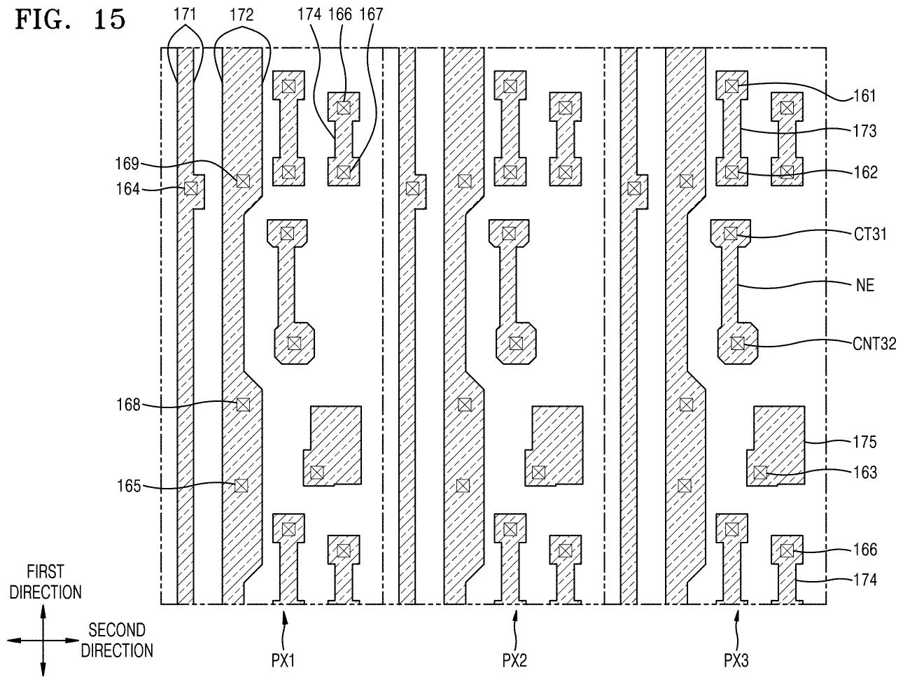

As shown in FIG. 15, the data line 171 and the power supply voltage line 172 may be above the third insulating layer 113. The data line 171 may be connected to the source region 176b of the second transistor T2 through a contact hole 164 defined in the first insulating layer 111, the second insulating layer 112, and the third insulating layer 113. The power supply voltage line 172 may be connected to the upper electrode CE2 of the capacitor Cst through a contact hole 168 defined in the third insulating layer 113, to the shielding member 150 through a contact hole 169 defined in the first insulating layer 111, the second insulating layer 112, and the third insulating layer 113, and to a lower semiconductor layer through a contact hole 165 defined in the first insulating layer 111, the second insulating layer 112, and the third insulating layer 113. The power supply voltage line 172 may be the first conductive line PL1. That is, the first conductive line PL1 extending in the first direction is connected to the upper electrode CE2 of the capacitor Cst extending in the second direction, so that the first conductive line PL1 may have a mesh structure.

Various conductive layers may be further arranged on the third insulating layer 113. In an exemplary embodiment, the node electrode NE and the connecting members 173, 174, and 175 may be disposed on a third insulating layer 113, for example. One end of the node electrode NE is connected to the drain region 177c of the third transistor T3 and the drain region 177d of the fourth transistor T4 through a contact hole CNT31 defined in the first insulating layer 111, the second insulating layer 112, and the third insulating layer 113, and the other end of the node electrode NE is connected to the gate electrode 125a of the first transistor T1 through a contact hole CNT32 defined in the second insulating layer 112 and the third insulating layer 113. The other end of the node electrode NE is connected to the gate electrode 125a of the first transistor T1 (or the lower electrode CE1 of the capacitor Cst) through the opening 27 defined in the upper electrode CE2 of the capacitor Cst. One end of the connecting member 173 may be connected to the first initialization voltage line 141 through a contact hole 161 defined in the third insulating layer 113, and the other end of the connecting member 173 may be connected to the source region 176d of the fourth transistor T4 through a contact hole 162 defined in the first insulating layer 111, the second insulating layer 112, and the third insulating layer 113. One end of the connecting member 174 is connected to the second initialization voltage line 142 through a contact hole 166 defined in the third insulating layer 113, and the other end of the connecting member 174 is connected to the drain region 177g of the seventh transistor T7 through a contact hole 167 defined in the first insulating layer 111, the second insulating layer 112, and the third insulating layer 113. The connecting member 175 may be connected to the drain region 177f of the sixth transistor T6 through a contact hole 163 defined in the first insulating layer 111, the second insulating layer 112, and the third insulating layer 113. The connecting member 175 may be electrically connected to the pixel electrode 151.

The fourth insulating layer 114 may be above the data line 171 and the power supply voltage line 172. The second conductive line PL2 may be above the fourth insulating layer 114 as shown in FIG. 8. The second conductive line PL2 may include the first extensions L1 in the first direction and the second extensions L2 in the second direction. The first extensions L1 may include the first sub conductive line SPL1 and the second sub conductive line SPL2. The second extensions L2 may include the third sub conductive line SPL3 and the fourth sub conductive line SPL4. The third sub conductive line SPL3 and the fourth sub conductive line SPL4 may partially overlap at least one of the first scan line 121, the second scan line 122, the third scan line 123, and the emission control line 124.

A connection electrode CM may further be above the fourth insulating layer 114. The connection electrode CM may be an electrode for connecting the organic light-emitting device OLED with a transistor. The connection electrode CM may be an electrode for connecting each of the first to third pixel electrodes 151R, 151G, and 151B with a source electrode or a drain electrode of the transistor. The connection electrode CM may be connected to the drain region 177f of the sixth transistor T6 by being connected to the connecting member 175 through a fourth contact hole CNT4 passing through the fourth insulation layer 114.

The connection electrode CM may include the same material and be provided in same layer as the second conductive line PL2. In an exemplary embodiment, the connection electrode CM may include Al, Pt, Pd, Ag, Mg, Au, Ni, Nd, Ir, Cr, Li, Ca, Mo, Ti, W and/or Cu, and may be a single layer or multiple layers of the above-described material, for example. The connection electrode CM may partially overlap the first to third openings OP1, OP2, and OP3 of the pixel defining layer in a plan view, that is, the first to third light-emitting regions EA1, EA2, and EA3.

The fifth insulating layer 115 may be above the second conductive line PL2. The organic light-emitting device OLED may be above the fifth insulating layer 115. As shown in FIGS. 8 and 9, the organic light-emitting device OLED may include the pixel electrode 151, the opposite electrode 153, and the intermediate layers 152R, 152G and 152B between the pixel electrode 151 and the opposite electrode 153.

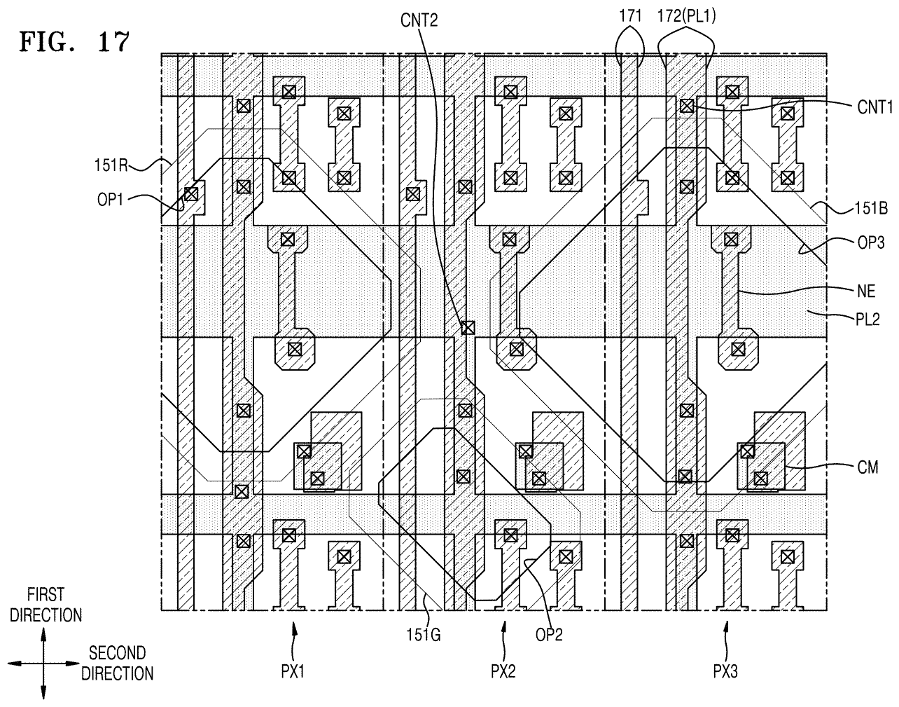

FIG. 17 is a view showing a relationship between the pixel electrode 151 of the first to third pixels PX1, PX2, and PX3, the first conductive line PL1, and the second conductive line PL2.

The first conductive line PL1 may be the power supply voltage line 172. The node electrodes NE may be in the same layer as the first conductive line PL1. The node electrodes NE may be spaced apart from each other between the first conductive lines PL1.

The second conductive line PL2 may overlap the first conductive line PL1. The second conductive line PL2 may be electrically connected to the first conductive line PL1 by the first contact holes CNT1 and the second contact holes CNT2. The second conductive line PL2 may at least partially overlap the node electrodes NE. The second conductive line PL2 may be on a layer between the node electrode NE and the first pixel electrode 151R or between the node electrode NE and the third pixel electrode 151B.

The first pixel electrode 151R of the first pixel PX1 may partially overlap the node electrode NE of the first pixel PX1 and the node electrode NE of the second pixel PX2 of a column adjacent to the left side of the first pixel PX1 (not shown). The third pixel electrode 151B of the third pixel PX3 may partially overlap the node electrode NE of the third pixel PX3 and the node electrode NE of the second pixel PX2 of the column adjacent to the left side of the third pixel PX3.

The first to third openings OP1, OP2, and OP3 of the sixth insulating layer 116 may overlap one of intersections of the second conductive line PL2, respectively. In another exemplary embodiment, as shown in FIG. 10, each of the first and third openings OP1 and OP3 may overlap one of the intersections of the second conductive line PL2, and the second openings OP2 may not overlap the intersections of the second conductive line PL2. Here, the second openings OP2 may overlap only the second sub conductive line SPL2 of the second conductive line PL2.

According to various exemplary embodiments of the invention, an asymmetric color shift phenomenon of an organic light-emitting display device is minimized while maintaining uniform characteristics between pixels, thereby ensuring uniformity of a right WAD and a left WAD. However, the scope of the invention is not limited to the effect.

It should be understood that embodiments described herein should be considered in a descriptive sense only and not for purposes of limitation. Descriptions of features within each exemplary embodiment should typically be considered as available for other similar features in other exemplary embodiments. While exemplary embodiments have been described with reference to the drawing figures, it will be understood by those of ordinary skill in the art that various changes in form and details may be made therein without departing from the spirit and scope as defined by the following claims.

What is claimed is:

1. A display device comprising:
a plurality of node electrodes;
a conductive layer above the plurality of node electrodes and comprising first extensions extending in a first direction and second extensions extending in a second direction intersecting the first direction;
a plurality of pixel electrodes above the conductive layer; and
an insulating layer covering an edge of each of the plurality of pixel electrodes,
wherein a plurality of openings respectively corresponding to a portion of each of the plurality of pixel electrodes is defined in the insulating layer,
a center of each of the plurality of openings overlaps one of intersections between the first and second extensions, and
the conductive layer overlaps the plurality of node electrodes.

2. The display device of claim 1, wherein
the first extensions comprise first sub conductive lines and second sub conductive lines alternately arranged with the first sub conductive lines, and
the second extensions comprise third sub conductive lines and fourth sub conductive lines alternately arranged with the third sub conductive lines.

3. The display device of claim 2, wherein
the third sub conductive lines overlap the plurality of node electrodes.

4. The display device of claim 2,
a width of the third sub conductive lines is greater than a width of the fourth sub conductive lines.

5. The display device of claim 2, wherein
the plurality of pixel electrodes comprises a first pixel electrode of a first pixel emitting a first color, a second pixel electrode of a second pixel emitting a second color, and a third pixel electrode of a third pixel emitting a third color,
wherein the first pixel electrode and the third pixel electrode are alternately arranged in the first direction and the second direction, and
the second pixel electrode is repeatedly arranged in the first direction and the second direction and separated in a diagonal direction away from the first pixel electrode and the third pixel electrode.

6. The display device of claim 5, wherein
the first pixel electrode and the third pixel electrode respectively overlap node electrodes at opposite sides of intersections between the first sub conductive lines and the third sub conductive lines.

7. The display device of claim 5, wherein
the plurality of openings of the insulating layer comprises a first opening corresponding to a portion of the first pixel electrode, a second opening corresponding to a portion of the second pixel electrode, and a third opening corresponding to a portion of the third pixel electrode.

8. The display device of claim 7, wherein
each of a center of the first opening and a center of the third opening overlaps one of first intersections between the first sub conductive lines and the third sub conductive lines, and
a center of the second opening overlaps one of second intersections between the second sub conductive lines and the fourth sub conductive lines.

9. The display device of claim 1, further comprising:
a plurality of conductive lines extending in the first direction in a same layer as the plurality of node electrodes, and electrically connected to the conductive layer.

10. The display device of claim 9, wherein
the plurality of node electrodes are between the plurality of conductive lines in the second direction.

11. The display device of claim 9, wherein
the plurality of conductive lines transmit a power supply voltage to pixels.

12. A display device comprising:
a plurality of node electrodes;
a conductive layer above the plurality of node electrodes and comprising first extensions extending in a first direction and second extensions extending in a second direction intersecting the first direction;
a plurality of pixel electrodes above the conductive layer; and
an insulating layer covering an edge of each of the plurality of pixel electrodes,
wherein a plurality of openings respectively corresponding to a portion of each of the plurality of pixel electrodes is defined in the insulating layer,
a center of each of first openings of the plurality of openings overlaps one of intersections between the first and second extensions, a center of each of second openings of the plurality of openings does not overlap the intersections, and
the conductive layer overlaps the plurality of node electrodes.

13. The display device of claim 12, wherein
the second extensions overlap the plurality of node electrodes.

14. The display device of claim 12, wherein
the first extensions comprise first sub conductive lines and second sub conductive lines alternately arranged with the first sub conductive lines.

15. The display device of claim 14, wherein
the plurality of pixel electrodes comprise a first pixel electrode of a first pixel emitting a first color, a second pixel electrode of a second pixel emitting a second color, and a third pixel electrode of a third pixel emitting a third color,
wherein the first pixel electrode and the third pixel electrode are alternately arranged in the first direction and the second direction, and
the second pixel electrode is repeatedly arranged in the first direction and the second direction and separated in a diagonal direction away from the first pixel electrode and the third pixel electrode.

16. The display device of claim 15, wherein
the first pixel electrode and the third pixel electrode respectively overlap node electrodes at opposite sides of intersections between the first sub conductive lines and the second extensions.

17. The display device of claim 15, wherein
the first openings comprise an opening corresponding to a portion of the first pixel electrode and an opening corresponding to a portion of the third pixel electrode, and
the second openings comprise an opening corresponding to a portion of the second pixel electrode.

18. The display device of claim 17, wherein
a center of each of the first openings overlaps one of intersections between the first sub conductive lines and the second extensions.

19. The display device of claim 12,
further comprising: a plurality of conductive lines extending in the first direction in a same layer as the plurality of node electrodes, and electrically connected to the conductive layer.

20. The display device of claim 19, wherein
the plurality of node electrodes are between the plurality of conductive lines in the second direction.
